(19) United States
(12) Patent Application Publication
(10) Pub. No.: US 2010/0151238 A1
(43) Pub. Date: Jun. 17, 2010

(54) ADHESIVE TAPE, PARTICULARLY FOR BONDING OPTOELECTRONIC COMPONENTS

(75) Inventors: Axel Burmeister, Buchholz (DE); Bernd Bunde, Hamburg (DE)

Correspondence Address: Briscoe, Kurt G.;Norris McLaughlin & Marcus, PA, 875 Third Avenue, 8th Floor, New York, NY, 10022, US

(73) Assignee: TESA SE, Hamburg (DE)

(21) Appl. No.: 12/622,209

(22) Filed: Nov. 19, 2009

(30) Foreign Application Priority Data
Dec. 16, 2008 (DE) 10 2008 062 131.5

(51) Int. Cl. B32B 15/085; H01L 31/042

(52) U.S. Cl. 428/344; 428/343; 136/251

(57) ABSTRACT

An adhesive tape for bonding optoelectronic components comprises a foam layer and two adhesive layers on the outside. The foam layer is located between top and bottom adhesive layers. A barrier film is, optionally, present between the adhesive layers.

### FIELD OF THE INVENTION

The invention relates to an adhesive tape intended more particularly for the adhesive bonding of optoelectronic components, with particular preference photovoltaic laminates.

### BACKGROUND OF THE INVENTION

Electronic and optoelectronic systems are being used more and more often in commercial products or are about to be introduced to the market. The term optoelectronics (sometimes also called optronics or optotronics) came about from a combination of optics and microelectronics, and in its widest sense encompasses all products and processes which allow the conversion of electronically generated data and/or energy into light emission and vice versa. Such systems include organic or inorganic electronic structures, examples being organic, organometallic or polymeric semiconductors or else combinations of these. Depending on the desired application, these systems and products are of rigid or flexible design. A technical challenge for the realization of a sufficient working life and function of (opto)electronic systems in the field of organic and/or inorganic (opto)electronics, especially in the field of organic (opto)electronics, is seen as being the protection of the components present therein against permeants. Permeants may be a multiplicity of organic or inorganic compounds of low molecular mass, more particularly water vapour and oxygen.

A multiplicity of (opto)electronic systems in the field of organic and/or inorganic (opto)electronics are sensitive in particular to water vapour. Throughout the useful life of the electronic system, therefore, protection by encapsulation is necessary, since otherwise the performance drops off over the period of application. Thus, for example, oxidation of the constituents may drastically reduce the luminosity power, in the case, for instance of light-emitting systems such as electroluminescent lamps (EL lamps) or organic light-emitting diodes (OLEDs), the contrast in the case of electrophoretic displays (EP displays), or the efficiency in the case of solar cells, within a very short time.

One approach which is common in the prior art, therefore, is to place the electronic system between two substrates that are impervious for permeants, more particularly water vapour. For inflexible constructions, glass or metal substrates are used predominantly, and offer a high permeation barrier. For flexible systems, on the other hand, sheet substrates such as transparent or non-transparent films are employed, which may be of multi-ply configuration. In this context it is possible to use not only combinations of different polymers, but also organic and/or inorganic layers. For the different applications and different sides, a very wide variety of different substrates are possible, such as films, fabrics, nonwovens and papers or combinations thereof, for example.

In order to obtain effective edge sealing not least in the case of particularly sensitive (opto)electronic components such as OLEDs, reactive adhesives are used. A good adhesive has low permeability in particular for oxygen and water vapour, exhibits adequate adhesion to the system, and is able to flow well on the latter. A low level of adhesion to the system reduces the barrier effect, if it allows oxygen and water vapour to enter at the interface between substrate and adhesive. In contrast to optoelectronic components, which comprise organic compounds that are sensitive to oxygen, no edge sealing with an adhesive, or even with an adhesive tape comprising a barrier film, is carried out in the case of the manufacturer of solar modules, since to date there has been no apparent need. It has been assumed so far that no oxygen barrier is needed because the side edges of the laminate are sufficiently protected from (rain)water by the bonding of the laminate into an aluminium frame at the edge by means of a silicone sealant or a foam adhesive tape.

For the encapsulation of (opto)electronic components such as OLEDs the adhesives used to date have primarily been liquid adhesives and epoxide-based adhesives (WO 98/21287 A1; U.S. Pat. No. 4,051,195 A; U.S. Pat. No. 4,552,604 A). As a result of a high level of crosslinking, these adhesives exhibit low permeability. Their principal field of use is in the edge bonding of rigid systems. Curing takes place thermally or by means of UV radiation.

Particular optoelectronic components are photovoltaic modules. Photovoltaics is the direct conversion of radiative energy, principally the energy of the sun, into electrical energy with the aid of solar cells. There are various embodiments of solar cells, the most widespread being thick-layer silicon cells, either as monocrystalline cells (c-Si) or multicrystalline cells (mc-Si). Increasingly widespread are thin-film cells made of amorphous silicon (a-Si), GaAs (gallium arsenide), CdTe (cadmium telluride), CIS (copper, indium, selenium), CIGS (copper, indium, gallium, selenium), and also organic solar cells and dye cells.

For the purpose of obtaining energy, solar cells are usually connected to form large solar modules, known as PV modules. For this purpose the cells are connected in series with conductor tracks on the front and rear. This results in addition of the voltage of the individual cells. Moreover, the solar cells are typically processed as a laminate, that is, in particular, provided on the top and bottom sides with a barrier material (glass, films, etc.).

The manufacture of a solar module is accomplished most frequently with the optically active side downwards. Generally, a corresponding glass is cleaned and placed ready. The glass is typically a low-iron, tempered white glass in a thickness of 3 to 4 mm, with very low absorption between 350 nm and 1150 nm. Atop this glass then comes a cut-to-size sheet of ethylene-vinyl acetate film (EVA film). The solar cells are joined by means of solder ribbons to form individual strands (called strings) and positioned on the top side of this EVA film. Then the interconnects which are intended to connect the individual strings to one another and which lead to the site of the connection socket are positioned and soldered. Subsequently the whole is covered in succession with cut-to-size EVA films and polyvinyl fluoride films (e.g. Tedlar™) or with an assembly of EVA, polyester and polyvinyl fluoride. The next step in production is the laminating of the module under a reduced pressure of around 20 mbar and at around 150° C. At the laminating stage, the EVA film, which up to that point has been milky, turns into a clear, three-dimensionally crosslinked plastic layer that can no longer be melted, and the solar cells are embedded in this layer, and the layer is firmly connected to the glass screen and the back-side film. Following lamination, the edges are trimmed, the connection socket is fitted, and the laminate is populated with freewheeling diodes. The laminate is thus complete.

PV modules are provided, for reasons of stability, with a frame, more particularly an aluminium frame, which serves both for assembly and for protection of the PV modules from fracture with the consequence of excessive bending. The connection between frame and laminate, which typically comprises the glass, polymer films, back-side film and solar cells, is solved, for example, through the application of a double-sided foam adhesive tape. This tape is bonded typically to the laminate edge and optionally is also wrapped round onto the bottom and/or top sides of the laminate, where it is pressed down. The laminate thus equipped is then pressed with a very high force into the frame groove. The sensitive laminate, as already described above, is generally protected on its top side, i.e. the optically active side, by a glass layer against water vapour or water, and on the bottom side either by a second glass layer or by a film or film composite with barrier effect. The laminate edges, in contrast, are protected only by the foam adhesive tape against the ingress of water. As the PV modules grow in size, particularly in the case of tracker modules, i.e. modules which use motors to track the position of the sun, an ever greater force is required to press the laminates into the frames. Pressing is particularly critical at the corners of the laminate, since, in the case of wrapping or overlapping, there is a double thickness of adhesive tape here. When the module is being pressed in, therefore, the adhesive tape may be damaged, possibly producing cracks in the foam, through which, in turn, rainwater may penetrate to the laminate edge. If water penetrates into the laminate, the adhesion between glass and EVA may be impaired. It has been found that, in the case of modules with EVA encapsulation films, the performance of the module drops over time. As well as yellowing or clouding of the EVA film, further causes which play a part are corrosion of the solder connections of the cell connectors, and creep currents. Moisture, apparently by hydrolysis of EVA, causes release of acetic acid, which on the one hand is corrosive and on the other hand considerably increases the conductivity. As a result of this there may be electrical losses in particular between laminate edge and frame.

As alternatives to adhesive bonding with a foam adhesive tape, the connection between frame and laminate may be realized by the introduction of crosslinkable silicone or a liquid adhesive into the frame groove. This in turn has the disadvantage that the swelling silicone or the liquid adhesive requires laborious removal, using solvents. Furthermore, in the case of damage to the back-side barrier film of the laminate, the frame can no longer be removed for repair operations.

### SUMMARY OF THE INVENTION

The present invention therefore addresses the problem of providing a means of providing the edges of laminates for PV modules with protection against water, simultaneously with the adhesive installation of the laminate.

This object is achieved by means of an adhesive tape according to Claim 1. An alternative adhesive tape for solving the problem is described by Claim 4. Preferred embodiments and developments are subject matter of the respective dependent claims.

An adhesive tape is proposed which is easy to apply and ensures a degree of protection of the laminate edge from water/water vapour penetration that is like that ensured by the laborious silicone sealing.

It has emerged that a foam adhesive tape, despite the danger of damage to the foam in the course of enframing, is suitable for sealing provided this adhesive tape additionally comprises a suitable barrier film. Given an appropriate arrangement, the barrier film is sufficiently protected, and so in general, even in the event of damage to the mechanically sensitive foam, the film is unaffected and hence the barrier effect of the adhesive tape is maintained. Contrary to all expectation, moreover, the adhesive tape can be placed readily around the laminate corners and edges, without the adhesive tape lifting, in spite of the significantly increased resilience. This applies in particular to the preferred form of application where the side with the barrier film faces the laminate edge, and the side with the foam faces the frame.

Furthermore, the barrier film affords the advantage that as a result of this film the adhesive tape overall has a more dimensionally stable design, particularly with respect to extension. This is the case in particular when the barrier film is composed, preferably, of a layer of an oriented film, as for example of a metallized polyester film or of a polyolefin film which has been oriented biaxially or, preferably, monoaxially in machine direction.

This not only makes it easier to apply the adhesive tape, but protection of this kind against over extension also translates into lower losses due to creep currents. The reason for this is probably that protection against overstretch leads to more precise lengths of the adhesive tape. By avoidance of overlengthening, it is possible to avoid the thick overlaps of the adhesive tape and hence excessive forces when the tape is pressed into the frame groove. If, conversely, the adhesive tape is even slightly too short, then channels form at the corners of the module edges, at which the adhesive tapes abut one another, and rainwater runs into the channels, from where the water may penetrate into the EVA layer. Owing to the conductivity of rainwater, this leads to a creep current between cells and metal frame via EVA layer and channels, producing losses in electrical performance.

A particular surprise was that, through the use of special polymer layers of the barrier film, with a low volume resistance, it is possible to achieve a considerable reduction in the creep current between solar cell and the (earthed) metal frame, even if the EVA layer has already absorbed moisture. If the layer is composed of non-hydrolysable polymers, then the electrical insulation effect remains intact, even after prolonged water exposure.

### BRIEF DESCRIPTION OF THE DRAWINGS

Further details, objectives, features and advantages of the invention will be elucidated in more detail below, with reference to an example. In the drawing

FIG. 1 shows a diagrammatic representation of a test laminate for determining the conductivity,

FIG. 2 shows the edge bonding of a PV module in diagrammatic representation, and

FIG. 3 shows the measurement setup for determining the conductivity.

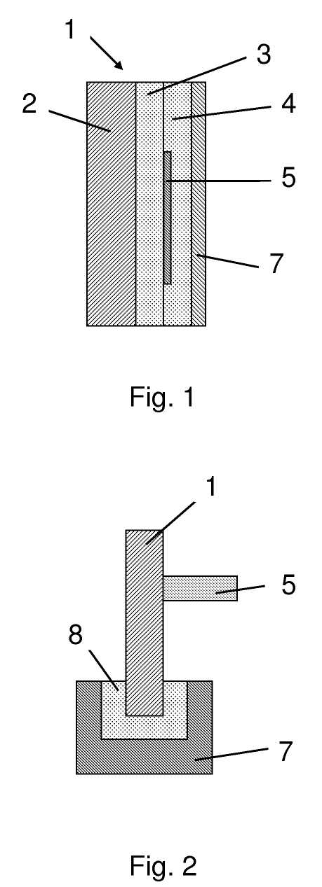

### DETAILED DESCRIPTION

The adhesive tape of the invention according to Claim 1 has a foam layer and a barrier film between the two outer pressure-sensitive adhesive layers. One adhesive layer serves for bonding to the laminate edge, and the other to the frame. The adhesive tape is preferably pressed onto the laminate edge with one adhesive layer and then wrapped round onto the top and/or bottom sides of the laminate. It has been found that, given a good barrier layer and sufficient adhesion of the adhesive, the diffusion of water through the adhesive layer becomes the weak point of the barrier. The cross section for diffusion should therefore be made as small as possible, and the diffusion pathway particularly long, in other words such that the adhesive tape is bonded as far as possible not only to the laminate edge but also to the glass plate and the back side. In order to make the cross section for diffusion small, the thickness of the adhesive layer is preferably less than 100 μm, more preferably less than 60 μm.

To simplify production, barrier film and foam layer of the adhesive tape preferably have the same thickness. In one particular embodiment, however, the foam layer or, preferably, the barrier film may protrude at the edge of the adhesive tape.

In a further-preferred embodiment, a foam layer only comes about, preferably, after application of the adhesive tape, by activation of a foaming agent in a polymer layer. As soon as activation has taken place, by means of supplying of heat, for example, closed cells form within the polymer layer, and hence the foam layer is formed. Activation takes place preferably only after the laminate has been inserted into the frame, in order to avoid any mechanical loading in the course of insertion. Foaming produces a particularly good seal between adhesive tape and frame and/or laminate. Any small channels formed at the abutting edges as a result of adhesive tape strips which are slightly too short are sealed by the foaming process.

In one alternative embodiment, according to Claim 4, the adhesive tape does not have an additional foam layer or foamable polymer layer; instead, at least one of the adhesive layers is itself designed in such a way as to take on the function of the foam layer. This is achieved by the adhesive layer comprising a foaming agent which, after foaming, leads to an adhesive layer with closed cells within itself. Activation takes place preferably by supplying of heat.

Preference is given to an embodiment in which the adhesive or the polymer layer comprising the foaming agent has a volume after foaming which is increased by at least 30%, preferably by at least 50%.

Of preferential suitability is an embodiment in which the foam layer or the foamable polymer layer or adhesive has a layer thickness after foaming in the range from about 100 μm to about 3000 μm.

With both alternatives of the adhesive tape it is possible for there to be further layers provided in addition to the layers described. In a preferred embodiment the connection of the barrier film to the foam layer takes place through a further adhesive layer. To improve the adhesion between adhesive and at least one of the layers, a physical pretreatment such as corona or plasma and/or a chemical adhesion promoter layer is preferred.

Furthermore, the adhesive layers are typically lined with a liner (for example silicone release paper or release film) which is removed prior to application.

As adhesives it is possible to use not only pressure-sensitive but also heat-activable adhesives. Pressure-sensitive adhesives in this sense also include those adhesives which at room temperature have little or no tack but exhibit tack properties above room temperature. Particularly when ease of applicability is a primary concern, however, preference is given to those pressure-sensitive adhesives which are already tacky at 23° C. Heat-activable adhesives are suitable especially when heating alone is required to activate the foaming agent. Furthermore, each of the adhesive layers present in an adhesive tape may well be of different construction, i.e. contain different adhesive compositions or have different layer thicknesses, etc. Adhesive tapes for the purposes of this invention are adhesive tape rolls and also sections thereof. Sections lined with a liner are also referred to typically in the trade as labels, and are hereby expressly included. Preference, however, is given to an adhesive tape in roll form.

Suitable foaming agents include, in particular, microballoons, which are present in a polymer layer, more particularly an adhesive layer. (Self-)adhesives foamed by means of microballoons have for a long time been known and described (DE 10 2004 037 910 A1). They feature a defined cell structure with a uniform size distribution of the foam cells. Closed-cell microfoams without cavities are formed in this case, thus making it possible, in comparison to open-cell versions, to obtain better sealing of sensitive products towards dust and liquid media.

Microballoons are, in particular, elastic, hollow spheres which have a thermoplastic polymer shell. These spheres are filled with low-boiling liquids or liquefied gas. Shell materials used are, in particular, polyacrylonitrile, PVDC, PVC or polyacrylates. Particularly suitable low-boiling liquids are hydrocarbons of the lower alkanes, isobutane or isopentane for example, which are enclosed in the form of a liquefied gas under pressure in the polymer shell. Action on the microballoons, in particular the action of heat, has the effect of softening the outer polymer shell. At the same time the liquid repellent gas located in the shell undergoes conversion to its gaseous state. In this process, the microballoons expand irreversibly and three-dimensionally. Expansion comes to an end when the internal pressure equals the external pressure. Since the polymeric shell remains intact, a closed-cell foam is obtained in this way.

By virtue of their flexible, thermoplastic polymer shell, foams of this kind possess a greater conformability than those filled with non-expandable, non-polymeric, hollow microbeads (such as hollow glass beads, for example). Furthermore, foams of this kind are better capable of compensating manufacturing tolerances, of the kind which are the rule, for example, in the case of injection mouldings, and the foams, by virtue of their foam character, are also better able to compensate thermal stresses.

Moreover, through the selection of the thermoplastic resin of the polymer shell, it is possible to exert further influence on the mechanical properties of the foam. Thus, for example, it is possible—even when the foam is less dense than the matrix—to produce foams having a high cohesive strength than with the polymer matrix alone. For instance, typical foam properties such as conformability to rough substrates can be combined with a high cohesive strength for PSA foams.

Conventionally chemically or physically foamed materials, in contrast, are more susceptible to irreversible collapse under pressure and temperature. Here, in addition, the cohesive strength is lower.

A large number of types of microballoon are available commercially, such as, for example, from Akzo Nobel the Expancel DU (dry unexpanded) types, which differ essentially in their size (6 μm to 45 μm in diameter in the unexpanded state) and in the initial temperature they require for expansion (75° C. to 220° C.). When the type of microballoon and/or the foaming temperature has been matched to the machine parameters and to the temperature profile needed for compounding the composition, compounding of the composition and coating may be carried out such that the microballoons do not foam in the course of processing and retain their entire expansion potential for the application.

Moreover, unexpanded types of microballoon are also obtainable in the form of an aqueous dispersion having a solids fraction or microballoon fraction of about 40% to 45% by weight, and additionally in the form of polymer-bound microballoons (masterbatches), for example in ethylene-vinyl acetate with a microballoon concentration of about 65% by weight. Not only the microballoon dispersions but also the masterbatches, like the DU products, are particularly suitable for the foaming of adhesives.

As well as adhesives and polymers foamed with microballoons, other foams are also outstandingly suitable that are provided in the form of a layer of foam in the adhesive tape. Particularly suitable are radiation-crosslinked, closed-cell EVA foams and, in particular, polyethylene foams such as, for example, those available from Sekisui-Alveo. It is also possible, moreover, to use foams of polypropylene, polyurethane or chloroprene rubber.

Particularly suitable for application in solar modules are foams having a density of at least 50 kg/m³, preferably of at least 67 kg/m³. Furthermore, the foams ought as far as possible not to exceed a density of 500 kg/m³. With particular preference the density of the foams is not more than 200 kg/m³.

Suitable pressure-sensitive adhesives for the outer layers include, for example, those based on polyisobutylene, butyl rubber, hydrogenated styrene block copolymers, especially polyolefins, solvent-based acrylate polymers and hotmelt acrylate polymers.

The pressure-sensitive adhesive can be crosslinked by chemical crosslinking and/or by electronic and/or UV irradiation.

As tackifiers it is possible to use tackifier resins. Suitable tackifier resins are resins based on rosin or rosin derivatives, polymers of diicyclopentadiene, of aliphatic C5 or aromatic C9 hydrocarbon resins, α-pinene, β-pinene or δ-limonene. Said tackifier resins may be used either alone or in a mixture. Preferred resins are those which are at least partly, but more preferably fully, hydrogenated.

Further additives which can be utilized typically for adhesives include the following:
primary antioxidants, such as sterically hindered phenols, for example
secondary antioxidants, such as phosphites or thioethers, for example
in-process stabilizers, such as C-radical scavengers, for example
light stabilizers, such as UV absorbers or sterically hindered amines, for example
processing assistants
endblock reinforcer resins and
plasticizers such as liquid polyisobutylene, mineral oil or liquid resins

In one preferred embodiment at least one adhesive is based on a polyacrylate or an EVM (ethylene-vinyl acetate elastomer); these systems are notable for high ageing stability, ready availability, and very high bond strength.

Particular preference is given to adhesives composed of partially crystalline polyolefins having a density of between 0.86 and 0.89 g/cm³, preferably between 0.86 and 0.88 g/cm³, more preferably between 0.86 and 0.87 g/cm³, and a crystallite melting point of at least 90° C., preferably of at least 115° C., more preferably of at least 135° C.

Furthermore, in a preferred embodiment, the partially crystalline polyolefins are combined with at least one tackifier resin. Completely innovative adhesives of this kind have a high ageing resistance, low costs, and, in comparison to conventional pressure-sensitive adhesives such as polyacrylate, a very much lower specific volume resistance and water vapour transmission rate (WVTR). The greater the amount of resin or the higher the softening point of the resin, the lower the WVTR.

The barrier film used is distinguished by low water vapour permeation, in order to be able to protect the sensitive laminate edge. Permeation is understood as the process in which a substance (permeate) penetrates or migrates through a solid. The driving force is a concentration gradient. The barrier effect is commonly characterized by specifying the water vapour transmission rate WVTR. This rate indicates the flow of water vapour, per unit area and unit time, through a planar object under specific conditions of temperature and partial pressure and also, where appropriate, further measurement conditions such as relative atmospheric humidity. The lower the WVTR, the more suitable the respective material for encapsulation. Barrier films for the purposes of this invention are understood by us to be those which have a WVTR of less than 5, preferably less than 0.7, and more preferably less than 0.01 g/m².d as measured at 37.8° C. and 90% relative humidity (d=day=24 h).

The barrier film may be composed for example of polyolefins, EVA with a VA fraction of less than 20% by weight, PVC, PVDC, polystyrene, ABS, polyacrylonitrile (for example Barex™), LCP, fluoropolymers such as ETFE or PVF, or organic-inorganic sol gels. Preferred films are those made from polymers which have a specific volume resistance at 20° C. of at least 10¹⁶ Ωcm, and more particularly those which are not susceptible to a reduced specific volume resistance as a result of moisture absorption and/or hydrolysis. Less preferred, therefore, are polyesters such as PET or PEN, EVOH, polyamides and polyurethanes. Particularly preferred films are those based on homo-, co- or terpolymers of ethylene, of propylene or of 1-butene, since they absorb or transmit virtually no water and are unable to undergo hydrolysis to more conductive substances, and hence, inherently, have a specific volume resistance. In the case of co- or terpolymers, preferred comonomers are α-olefins such as ethylene, propylene, 1-butene, 1-hexene, 4-methylpentene or 1-octene.

The barrier effect can be improved through addition of fillers, more particularly of platelet-shaped fillers such as talc, since these particles can be oriented in the course of extrusion. A layer structure formed in this process leads to a lengthening of the diffusion pathway. The particles themselves, like glass, are completely impermeable to gases. Where there is a need for transparency, such fillers can be nanoscale.

Barrier films with a thickness of 0.5 μm to 120 μm are used with preference in order to obtain a sufficient permeation effect while not greatly increasing the stiffness of the adhesive tape.

Suitability is possessed, for example, by films comprising a film part, formed by at least one polymeric film, of polyester in particular, and also comprising a metallic part which is applied to the film part and is formed of a metallic layer of, in particular, aluminium. The lower adhesive layer is preferably applied on the exposed side of the metallic layer.

In one advantageous embodiment the barrier film is composed of a metal foil such as aluminium or of a laminate or of an extrusion-coated assembly of a polymeric film such as a film vapour coated with metal, and of a polyolefin layer. In this case the metallic layer serves as a barrier layer and keeps the product to be protected away from corrosion-promoting substances such as oxygen, sulphur dioxide, carbon dioxide and, in particular, water or water vapour.

A particularly preferred barrier film is a metallized polyolefin or polyester film. In a first advantageous embodiment of the invention the metallic layer has a thickness of 10 nm to 50 μm, more particularly 20 nm to 25 μm. The metallic layer is applied to the film part by means, for example, of vapour coating, in other words by generating a coating on the polymeric film by means of thermal evaporation under vacuum (purely thermally, electrically with electron beams, by cathodic sputtering or wire explosion, if desired with the aid of laser beams).

It is also possible, furthermore, to employ laminates with three or more layers. Moreover, symmetrical laminate structures around a core of a metal layer may be advantageous in particular fields of application. Lamination or extrusion coating where the metal layer is enclosed between polymer layers prevents corrosion of the metal and is therefore preferred.

### Permeation Measurement by Flushing Gas Method

In an appropriate measuring cell for pipes, films and membranes, these can be examined for their permeability both to any desired gases and to liquids of all kinds. The measurement techniques for gases all include a central module which is divided by the membrane under test: on the feed side the measuring cell is overflowed with the test gas, and the retentate which remains is taken off. The amount of the gas arriving on the other side (permeate) is passed by the flushing gas to a detector, where the concentration is measured. Top and bottom parts of the cell surround the centred membrane. An O-ring which lies on the sample seals the interface. This kind of cell is usually manufactured of metal such as stainless steel, for example.

### Conductivity Measurement:

For the conductivity measurement, the following test elements were produced with dimensions of 195 mm×50 mm. The test element (laminate (1)) has the following: a 4.2 mm glass layer (2), 2 plys of 460 μm EVA film (3, 4) (Etimex Vistasolar FC 486.10), between which there is an aluminium film (5) 50 μm thick and 25 mm wide, and a 23 μm polyester film (6) as back-side film. The aluminium film (5) was passed at a distance of 17 mm to the short sides of the laminate through an EVA film (4) and the back-side film (6); on the long edge, the aluminium film (5) has a distance of 17 mm. The thickness of the laminate (1) is 5 mm. The laminate (1) described was produced as follows:
1) 2.5 minutes at 40° C., evacuate to 20 mbar
2) base temperature is raised over the course of 3.5 minutes from 40° C. to 133° C.; at the same time the upper area of the laminator is pressed onto the module until 780 mbar have been reached
3) when 780 mbar have been reached, crosslinking is carried out for 13 minutes at 133° C. and 780 mbar
4) the laminate is cooled to 40° C. for about 7 minutes.

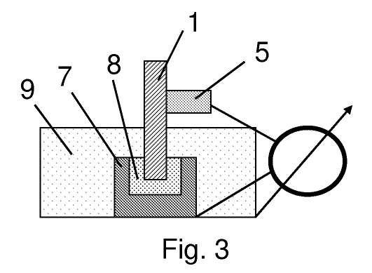

The laminate (1), provided at the edge and on the top and bottom sides with the test adhesive tape (8) in a width of 19 mm, is pressed into a U-shaped aluminium profile (FIG. 2) having a groove of 6 mm and a depth of 10 mm and made from aluminium 2 mm thick (frame (7) for short). The edges of the laminate (1) not protected by the frame (7) are sealed with silicone (Lugato “Wie Gummi” bath-silicone). The test element with the frame (7) is placed into a surfactant solution (9) made up of Liqui Nox/distilled water (1:500), available from Alconox, White Plains, N.Y. 10603 (FIG. 3), and the volume resistance is measured at 500 V after 2 minutes using a teraohmmeter (Megaohmmeter Insulation Tester MD 508).

### Example 1

### Comparative

An adhesive tape with a PE foam 1000 μm thick (Alveo), with a density of 67 kg/m³, is corona-treated and then provided on both sides with 50 g/m² of a resin-modified adhesive (tesa 4957) and subjected to measurement.
Permeation of water: 12 g/m² d
Conductivity measurement: short circuit (resistance <0.1 kohm)

The adhesive tape does not have a sufficient barrier effect; water is able to diffuse into the joint and short-circuit the conductor (aluminium foil) with the frame.

### Example 2

### Comparative

An adhesive tape with a PE foam 1000 μm thick, with a density of 67 kg/m³, is corona-treated and then provided on both sides with 50 g/m² of a resin-modified adhesive (tesa 4957). Furthermore, on the side facing the laminate edge, the adhesive tape is provided with a 23 μm polyester film and with an additional layer of adhesive which is identical to those specified above. The resulting product structure is as follows:
a) adhesive
b) foam
c) adhesive
d) polyester film
e) adhesive

The adhesive e) is facing the laminate edge.
Permeation of water: 10 g/m² d
Conductivity measurement: short circuit (resistance <0.1 kohm)

The adhesive tape does not have a sufficient barrier effect; water is able to diffuse into the joint and short-circuit the conductor (aluminium foil) with the frame.

### Example 3

### Inventive

An adhesive tape with a 1000 μm thick PE foam having a density of 67 kg/m³ is corona-treated and then provided on both sides with 50 g/m² of a resin-modified adhesive (tesa 4957). Additionally, on the side facing the laminate edge, a 23 μm polyester film which has been vapour-coated with a layer of aluminium 20 nm thick (Donmore Europe in 79111 Freiburg), and an additional layer of adhesive which is identical with those specified above, are applied. The resulting product structure is as follows:
a) adhesive
b) foam
c) adhesive
d) metallized polyester film
e) adhesive

The adhesive e) faces the laminate edge.
Permeation of water: 1 g/m² d
Conductivity measurement: 25 Mohm

The adhesive tape has a sufficient barrier effect; no water/water vapour is able to diffuse into the joint of the laminate and short-circuit the conductor (aluminium foil) with the frame.

### Example 4

### Inventive

An adhesive tape with a 1000 μm thick PE foam having a density of 67 kg/m³ is corona-treated and then provided on both sides with 50 g/m² of a resin-modified adhesive (tesa 4957). Additionally, on the side facing the laminate edge, a 12 μm polyester film with a 12 μm aluminium foil (Alcan Packaging Singen GmbH in 78221 Singen), and an additional layer of adhesive which is identical with that specified above, are applied. The resulting product structure is as follows:
a) adhesive
b) foam
c) adhesive
d) 12 μm polyester film/laminating adhesive/12 μm aluminium foil
e) adhesive

The adhesive e) faces the laminate edge.
Permeation of water: 0.6 g/m² d
Conductivity measurement: 225 Mohm

The adhesive tape has a sufficient barrier effect; no water/water vapour is able to diffuse into the joint of the laminate and short-circuit the conductor (aluminium foil) with the frame.

### Example 5

### Inventive

An adhesive tape is produced as per Example 4, the pressure-sensitive adhesives used being in each case an adhesive with the following composition:
a) 24 parts by weight of Notio PN 0040 (copolymer of propylene, but-(1)-ene and 4-methylpent-1-ene, melt index 4 g/10 min, density 0.868 g/cm³, flexural modulus 42 MPa, crystallite melting point 159° C., enthalpy of fusion 5.2 J/g)
b) 20 parts by weight of Oppanol B10 (liquid polyisobutene plasticizer, density=0.93 g/cm³; Mₙ=40 000 g/mol)
c) 54 parts by weight of Regalite 1100 (fully hydrogenated C9 hydrocarbon resin, melting point 100° C., polydispersity 1.4), and
d) 2 parts by weight of Irganox 1076 (phenolic antioxidant)
   Permeation of water: 0.1 g/m².d
   Conductivity measurement 430 Mohm

The adhesive tape has an improved barrier effect which underlines the importance of the composition of the adhesive for the diffusion of water through the outwardly exposed adhesive edge.

1. Adhesive tape at least comprising a foam layer and first and second adhesive layers on an outside of the adhesive tape, the foam layer being disposed between first and second adhesive layers, wherein a barrier film is located between the upper and lower adhesive layers.

2. Adhesive tape according to claim 1, wherein an additional adhesive layer is located between the foam layer and the barrier film.

3. Adhesive tape according to claim 1, wherein the foam layer is formed by a polymer layer comprising a foaming agent.

4. Adhesive tape comprising two adhesive layers on an outside of the adhesive tape, at least one adhesive layer being formed by a polymer layer comprising a foaming agent, wherein a barrier film is located between the layers of adhesive.

5. Adhesive tape according to claim 3, wherein the polymer layer is foamable by supply of heat and/or in that the polymer layer comprising the foaming agent exhibits, after foaming, a volume increased by at least 30%.

6. Adhesive tape according to claim 1, wherein the foam layer or adhesive, after foaming, has a layer thickness in a range from about 100 μm to about 3000 μm.

7. Adhesive tape according to claim 1, wherein the barrier film has a layer thickness in the range from about 0.5 μm to about 160 μm and/or in that the barrier film has a water vapor transmission rate of less than 5 g/m²d.

8. Adhesive tape according to claim 1, wherein the barrier film, in addition to a polymer film, has a metallic layer, in a form of a vapour-deposited metallic layer, in that the metallic layer has a thickness in a range from about 10 nm to about 50 μm.

9. Adhesive tape according to claim 1, wherein the barrier film is of multi-ply construction.

10. Adhesive tape according to claim 1, wherein the barrier film has a polymer layer having a specific volume resistance at 20° C. of at least 10¹⁶ Ocm.

11. Adhesive tape according to claim 1, wherein the barrier film comprises a polymer layer of a polyolefin.

12. Method comprising:
providing an adhesive tape according claim 1;
bonding a first optoelectronic component to a second optoelectronic component with the adhesive tape.

13. Adhesive tape according to claim 5, wherein, after foaming, the foaming agent exhibits a volume increased by at least 50%.

14. Adhesive tape according to claim 7, wherein the barrier film has a water vapor transmission rate of less than 0.7 g/m²d.

15. Adhesive tape according to claim 14, wherein the barrier film has a water vapor transmission rate of less than 0.1 g/m²d.

16. Adhesive tape according to claim 8, wherein the metallic layer has a thickness in the range from about 20 nm to about 25 μm.

17. Adhesive tape according to claim 9, wherein the barrier film has a metallic layer between a first polymer layer and a second polymer layer.

18. Adhesive tape according to claim 11, wherein the polymer layer is a homo-, co- or terpolymer of ethylene or propylene.

19. Adhesive tape according to claim 17, wherein the polymer layer is oriented.

20. Method according to claim 12, wherein the first optoelectronic component is a photovoltaic laminate and the second optoelectronic component is a frame of a photovoltaic module.
